(19) United States
(12) Patent Application Publication
(10) Pub. No.: US 2014/0353003 A1
(43) Pub. Date: Dec. 4, 2014

(54) TOUCH-SCREEN CONDUCTIVE FILM AND MANUFACTURING METHOD THEREOF

(71) Applicants: NANCHANG O-FILM TECH CO., LTD., Nanchang (CN); SUZHOU O-FILM TECH CO., LTD., Suzhou City (CN); SHENZHEN O-FILM TECH CO., LTD., Shenzhen City (CN)

(72) Inventors: YING GU, Nanchang (CN); Guanglong Xie, Nanchang (CN); Yunhua Zhao, Nanchang (CN); Fanchu Zeng, Nanchang (CN)

(73) Assignees: NANCHANG O-FILM TECH CO., LTD., Nanchang (CN); SUZHOU O-FILM TECH CO., LTD., Suzhou City (CN); SHENZHEN O-FILM TECH CO., LTD., Shenzhen City (CN)

(21) Appl. No.: 14/265,305

(22) Filed: Apr. 29, 2014

(30) Foreign Application Priority Data
May 30, 2013 (CN) 201310210456.6

(51) Int. Cl. H05K 1/02; H05K 3/46; H05K 3/12

(52) U.S. Cl. CPC H05K 1/0213; H05K 3/1208; H05K 3/4694
USPC 174/250; 216/14

(57) ABSTRACT

A touch-screen conductive film includes a transparent substrate, a conductive layer and a lead electrode. The transparent substrate includes a first area, and a second area disposed surrounding the first area; the conductive layer is disposed on the first area of the transparent substrate; the lead electrode is disposed on the second area of the transparent substrate. Since the conductive layer and the lead electrode are directly set on the transparent substrate, the touch-screen conductive film is of simple structure and low cost, furthermore, the thickness of the touch-screen conductive film is reduced. In addition, the present invention also provides a method for manufacturing a touch-screen conductive film.

### CROSS REFERENCE TO RELATED APPLICATIONS

This application claims priority to Chinese Patent Application No. 201310210456.6, filed on May, 30, 2013, entitled “TOUCH-SCREEN CONDUCTIVE FILM AND MANUFACTURING METHOD THEREOF”, which is hereby incorporated by reference in its entirety.

### TECHNICAL FIELD

The present invention relates to the field of touch-screen and, in particular, to a touch-screen conductive film and manufacturing method thereof.

### BACKGROUND

Touch-screen is a sensing device which may receive touching signals and the like as input signals. Touch-screen is a compelling and totally new information exchange device, which provides a new look to the information exchange. The development of touch-screen technology has aroused widespread attention from the information media, domestic and international, and has become a sunrise high-tech industry which suddenly emerged in the optoelectronic industry.

For the production of a touch-screen conductive film, the traditional method is to use nano-imprint technology, specifically the method includes: Step 1: photoetching, that is, forming a photoresist on a substrate, then photoetching the photoresist using a mask. Step 2: Developing, that is, developing the photoetched photoresist to obtain a conductive pattern groove on the photoresist. Step 3: Electroplating, that is, plating a layer of conductive silver on the photoresist which has the conductive pattern groove and then electroplating nickel, after finishing the electroplating and separating from the substrate, a nickel mold can be obtained. Step 4: Embossing, that is, embossing the nickel mold on a UV adhesive and then exposing and curing the UV adhesive to form a groove on the UV adhesive. Step 5: Printing, that is, brushing conductive ink in the groove of the UV adhesive and drying it to form a conductive grid. The conductive grid is attached to the substrate to obtain the touch-screen conductive film.

The touch-screen, produced by the conventional method of producing touch-screen conductive film, is of complex structure and high cost.

### SUMMARY

Therefore, there is a need to provide a touch-screen conductive film with simple structure and low cost, and a manufacturing method thereof.

A touch-screen conductive film includes: a transparent substrate having a first area and a second area disposed surrounding the first area; a conductive layer disposed on the first area of the transparent substrate, where the conductive layer is formed by conductive wires intercrossed to each other; and a lead electrode, disposed on the second area of the transparent substrate, and electrically connected to the conductive wires.

In an embodiment according to the present invention, a width of the conductive wire is 0.1 μm˜10 μm, a thickness of the conductive wire is 3 μm˜10 μm.

In an embodiment according to the present invention, the transparent substrate is a glass substrate.

In an embodiment according to the present invention, the conductive wires are intercrossed to constitute a plurality of conductive grids, and the conductive grids are regular grids or random grids.

In an embodiment according to the present invention, the touch-screen conductive film further includes a light shielding layer, the light-shielding layer is disposed on the second area of the transparent substrate, and the lead electrode is disposed on a side of the light-shielding layer away from the transparent substrate.

In an embodiment according to the present invention, the touch-screen conductive film further includes an adhesive layer disposed on the first area and the second area of the transparent substrate; the conductive layer and the light-shielding layer are connected to the transparent substrate via the adhesive layer, or, the adhesive layer covers the light shielding layer, the conductive layer is connected to the transparent substrate via the adhesive layer.

A method for manufacturing a touch-screen conductive film includes the following steps:

providing a transparent substrate having a first area and a second area disposed surrounding the first area;

forming a conductive layer on the first area of the transparent substrate, where the conductive layer is formed by conductive wires intercrossed to each other; and

forming a lead electrode on the second area of the transparent substrate, where the lead electrode is electrically connected to the conductive wires.

In an embodiment according to the present invention, the step of forming a conductive layer on the first area of the transparent substrate includes the following steps:

forming a photoresist in the first area of the transparent substrate;

photoetching and developing the photoresist to obtain a conductive groove;

printing in the conductive groove with a conductive solution and drying the conductive solution; and

removing remaining photoresist to obtain the conductive layer.

In an embodiment according to the present invention, the step of forming a lead electrode on the second area of the transparent substrate includes:

forming a photoresist in the second area of the transparent substrate;

photoetching and developing the photoresist to obtain a lead electrode groove;

printing in the lead electrode groove with a conductive solution and drying the conductive solution; and

removing remaining photoresist to obtain the lead electrode.

In an embodiment according to the present invention, after the step of providing a transparent substrate, and before the step of forming a conductive layer on the first area of the transparent substrate, the method further includes a step of coating adhesive glue in the first area and the second area of the transparent substrate, to obtain an adhesive layer, where the conductive layer and the lead electrode are both formed on a side of the adhesive layer away from the transparent substrate.

Since the conductive layer and the lead electrode are directly formed on the transparent substrate, compared with the conventional touch-screen conductive film and its conventional manufacturing method, the above mentioned touch-screen conductive film and its manufacturing method are of simple structure and low cost. Furthermore the thickness of the touch-screen conductive film is reduced, and manufacturing process is simplified.

### BRIEF DESCRIPTION OF DRAWINGS

FIG. 1 is a structural diagram of a touch-screen conductive film according to an embodiment;

FIG. 2 is a structural diagram of a transparent substrate according to an embodiment;

FIG. 3 is a structural diagram of a touch-screen conductive film according to another embodiment; and

FIG. 4 is a flowchart diagram of a method for manufacturing a touch-screen conductive film according to an embodiment.

### DESCRIPTION OF EMBODIMENTS

In order to facilitate understanding of the present invention, the present invention will be described more comprehensively in conjunction with the accompanying drawings. Shown in the drawings are the preferred embodiments of the present invention. However, the present invention can be implemented in many ways, and is not limited to the embodiments described herein. The purpose of these embodiments is to enable a more thorough and comprehensive disclosure of the present invention

It should be noted that, when an element is described as “fixed on” another element, it may be directly fixed on another element or there may also be other element existing therebetween. When an element is considered as “connected with” another element, it can be directly connected to another element or there may be other element existing therebetween in the meantime. As used herein, the term “vertical”, “horizontal”, “left”, “right” and similar expressions are for illustrative purpose only.

Unless defined otherwise, all of the technical and scientific terms used herein have the same meaning as that commonly understood by the person skilled in the art. The purpose of using the terms in the specification of the present invention is only for describing specific embodiments, other than to limit the scope of the present invention. As used herein, the term “and/or” includes any and all combinations of one or more associated listed items.

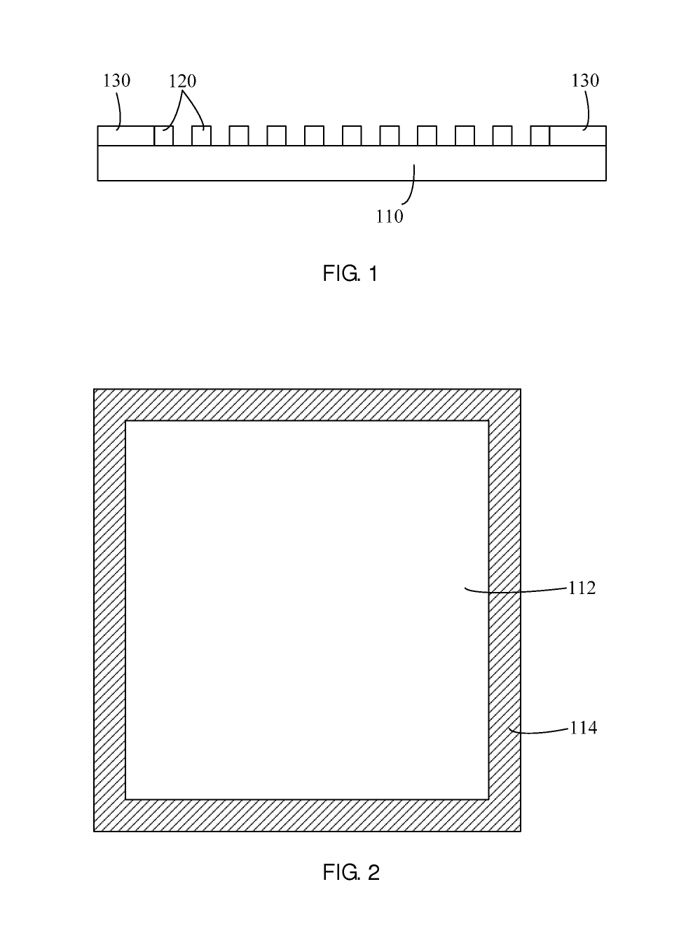

With reference to FIG. 1 and FIG. 2, a screen-touch conductive film includes a transparent substrate 110, a conductive layer 120, and a lead electrode 130.

The transparent substrate 110 includes a first area 112, and a second area 114 which is disposed surrounding the first area 112. The conductive layer 120 is disposed on the first area 112 of the transparent substrate 110, and the conductive layer 120 is formed by conductive wires intercrossed to each other. The lead electrode 130 is disposed on the second area 114 of the transparent substrate 110, and is electrically connected to the conductive wires of the conductive layer 120.

The transparent substrate 110 may be made of optically transparent material such as glass, polymethyl methacrylate (PMMA) or polyethylene terephthalate (PET). In this embodiment the transparent substrate 110 is a glass substrate, which can reduce production cost. The thickness of the transparent substrate 110 may be 50 μm˜300 μm, to ensure that neither will the transparent substrate 110 be easily damaged due to being too thin, nor will the touch-screen conductive film be too thick because of the transparent substrate 110 being too thick. The conductive wire of the conductive layer 120 may be at least one of metal wire, metal alloy wire, carbon nanotube wire, graphene wire and conductive polymer material wire. In this embodiment, the material of the conductive wire is silver, which can improve the conductivity of the touch-screen conductive film. The conductive wires are intercrossed to constitute a plurality of conductive grids, and the conductive grids may be regular grids, such as square, rectangular, triangular, rhombus or polygon. The shapes of different conductive grids may be all the same, partially same or different. By making the conductive grids regular grids, unified control of production can be facilitated. In other embodiments, the conductive grids may also be random grids, i.e., the shape of the grids are irregular.

In an embodiment, a width of the conductive wire may be 0.1 μm˜10 μm, to ensure that neither will the transmittance of the touch-screen conductive film be affected due to the conductive wire being too wide, nor will the conductivity of the touch-screen conductive film be affected due to the conductive wire being too narrow. A thickness of the conductive wire may be 3 μm˜10 μm, to ensure that neither will the conductivity of the touch-screen conductive film be affected due to the conductive wire being too thin, nor will the touch-screen conductive film be too thick due to the conductive wire being too thick.

The above mentioned touch-screen conductive film, given that the conductive layer 120 and the lead electrodes 130 thereof are directly disposed on the transparent substrate 110, is of simple structure and low cost, furthermore, the thickness of the touch-screen conductive film can be reduced.

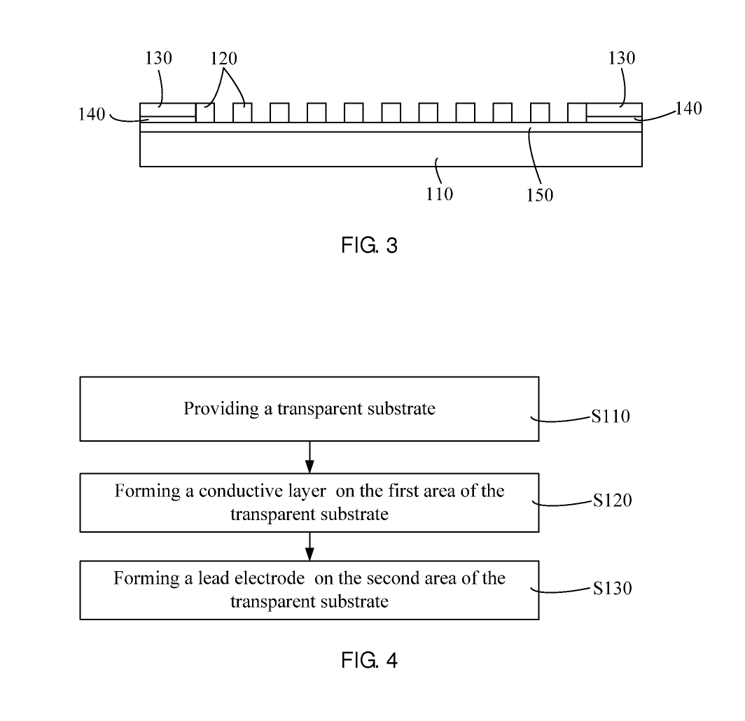

In an embodiment, with reference to FIG. 3, the touch-screen conductive film may further includes a light shielding layer 140, the light-shielding layer 140 is disposed on the second area of the transparent substrate 110, and the lead electrode 130 is disposed on a side of the light-shielding layer 140 away from the transparent substrate. The light-shielding layer 140 is used to shield the lead electrode 130. In this embodiment, the light shielding layer 140 may be an ink layer, which can be manufactured simply and at low cost, specifically it may be a black ink layer or a colored ink layer, as long as it satisfies the condition of being opaque and insulating.

Still with reference to FIG. 3, the touch-screen conductive film may further includes an adhesive layer 150 disposed on the first area and the second area of the transparent substrate 110. The adhesive layer 150 in this embodiment may be optical glue layer. The conductive layer 120 and the light-shielding layer 140 may both be disposed on one side of the adhesive layer 150 away from the transparent substrate 110, and connected to the transparent substrate 110 via the adhesive layer 150, so that the adhesion of the conductive layer 120 and the light-shielding layer 140 can be improved. In this implementation the shielding layer 140 also needs to be insulated. The light shielding layer 140 may be covered by the adhesive layer 150, the conductive layer 120 and the lead electrode 130 is disposed on one side of the adhesive layer 150 away from the light-shielding layer 140, the conductive layer 120 is connected to the transparent substrate 110 via the adhesive layer 150. In this implementation, the shielding layer 140 may be insulating or conductive.

In addition, the present invention further provides a method for manufacturing a touch-screen conductive film, with reference to FIG. 4, it includes the following steps:

Step S110: Provide a transparent substrate.

The transparent substrate includes a first area, and a second area which is disposed surrounding the first area, the transparent substrate 110 may be made of optically transparent materials such as glass, polymethyl methacrylate (PMMA) or polyethylene terephthalate (PET). In this embodiment the transparent substrate 110 is a glass substrate, which can reduce production cost. The thickness of the transparent substrate 110 may be 50 μm˜300 μm, which can ensure neither the transparent substrate 110 being easily damaged due to being too thin, nor making the touch-screen conductive film being too thick due to being too thick.

Step S120: Form a conductive layer on the first area of the transparent substrate.

The conductive layer is formed by conductive wires intercrossed to each other. The conductive wire of the conductive layer 120 may be at least one of metal wire, metal alloy wire, carbon nanotube wire, graphene wire and conductive polymer material wire. In this embodiment, the material of the conductive wire is metallic silver, which can improve the conductivity of the touch-screen conductive film. The conductive wires are intercrossed to constitute a plurality of conductive grids, and the conductive grids may be regular grids, such as square, rectangular, triangular, rhombus or polygon. The shapes of conductive grids may be all the same, partly same or not the same at all. By making the conductive grids regular grids, unified control of production can be facilitated. In other embodiments, the conductive grids may also be random grids, i.e., the shape of the grids are irregular.

In an embodiment, a width of the conductive wire may be 0.1 μm˜10 μm, which can ensure neither the transmittance of the touch-screen conductive film being affected due to being too wide of the conductive wire, nor the conductivity of the touch-screen conductive film being affected due to being too narrow of the conductive wire. A thickness of the conductive wire may be 3 μm˜10 μm, which can ensure neither the conductivity of the touch-screen conductive film being affected due to being too thin of the conductive wire, nor the touch-screen conductive film being too thick due to being too thick of the conductive wire.

Step S130: Form a lead electrode on the second area of the transparent substrate.

The lead electrode is electrically connected to the conductive wire.

Since the conductive layer and the lead electrodes are directly formed on the transparent substrate, compared with the conventional method for manufacturing a touch-screen conductive film, the above mentioned method for manufacturing a touch-screen conductive film is of a simple process. And the touch-screen conductive film manufactured by this method has a simple structure and low cost. Furthermore, the thickness of the touch-screen conductive film is reduced.

In an embodiment, the step S120 may includes the following steps:

forming a photoresist in the first area of the transparent substrate;

photoetching and developing the photoresist, to obtain a conductive groove;

printing the conductive groove with a conductive solution, and drying the conductive solution;

removing remaining photoresist to obtain the conductive layer.

The step S130 may includes the following steps:

forming a photoresist in the second area of the transparent substrate;

photoetching and developing the photoresist to obtain a lead electrode groove;

printing the lead electrode groove with a conductive solution, and drying the conductive solution;

removing remaining photoresist to obtain the lead electrode.

This embodiment provides the method of obtaining the conductive layer and the lead electrode directly by using lithography technique. It can be appreciated that, the conductive layer and the lead electrode may be obtained simultaneously by using the lithography technique, and production processes can be further reduced as well as the production cost be reduced. Compared with the conventional embossing method, the conductive layer and lead electrode directly obtained using lithography technique is finer and more accurate. In an embodiment, inkjet printing technique may also be used to obtain the lead electrode, which can be performed simply and fast.

In an embodiment, before step S130, the method may further include a step of providing a light-shielding layer in the second area of the transparent substrate, in order to shield the lead electrode. Specifically, this step may be performed after the step S110 or after the step S120. In this embodiment, the light shielding layer may be an ink layer, and it may be obtained by coating ink in the second area of the transparent substrate, which can be manufactured simply and at low cost, specifically it may be a black ink layer or a colored ink layer, as long as it satisfies the condition of being opaque and insulating. It can be appreciated that in other embodiments, the step of providing the light-blocking layer may be omitted.

In an embodiment, after the step S110 and before the step S120, the method may further include the following step:

coating adhesive glue in the first area and second area of the transparent substrate to obtain an adhesive layer.

The conductive layer and the lead electrode are both formed on one side of the adhesive layer away from the transparent substrate. Specifically the conductive layer is formed on one side of the adhesive layer away from the transparent substrate, at a place corresponding to the first area of the transparent substrate; the lead electrode is formed on one side of the adhesive layer away from the transparent substrate, at a place corresponding to the second area of the transparent substrate. The adhesive glue in this embodiment may be optical glue. The light-shielding layer may also be formed on one side of the adhesive layer away from the transparent substrate. The conductive layer and the light-shielding layer are connected to the transparent substrate via the adhesive layer, so that the adhesion of the conductive layer and the light-shielding layer can be improved. In this implementation the shielding layer also needs to be insulated. In another implementation, the adhesive layer may be formed after the light-shielding layer is formed, and then the conductive layer and the lead electrode are formed on the adhesive layer, that is, the adhesive layer covers the light-shielding layer, and the conductive layer and the lead electrode are located on one side of the adhesive layer away from the light-shielding layer, the conductive layer is connected to the transparent substrate via the adhesive layer. In this implementation, the shielding layer 140 may be insulated or conductive.

The foregoing embodiments merely describe several implementing modes of the present invention with specific details, and it should not be interpreted as limiting the present invention. It should be noted that, persons of ordinary skill in the art may make variants and modifications to the technical solutions described in the foregoing embodiments without departing from the concept of the present invention, all of these variants and modifications fall within the protection scope of the present invention. Accordingly, the scope of protection of the present invention should subject to the appending claims.

What is claimed is:

1. A touch-screen conductive film, comprising:
a transparent substrate having a first area and a second area disposed surrounding the first area;
a conductive layer disposed on the first area of the transparent substrate, the conductive layer is formed by conductive wires intercrossed to each other; and
a lead electrode disposed on the second area of the transparent substrate and electrically connected to the conductive wires.

2. The touch-screen conductive film according to claim 1, wherein a width of the conductive wires has a range of 0.1 μm˜10 μm, a thickness of the conductive wires is 3 μm˜10 μm.

3. The touch-screen conductive film according to claim 1, wherein the transparent substrate is a glass substrate.

4. The touch-screen conductive film according to claim 1, wherein the conductive wires are intercrossed to constitute a plurality of conductive grids, and the conductive grids are regular grids or random grids.

5. The touch-screen conductive film according to claim 1, further comprising a light shielding layer, wherein the light-shielding layer is disposed on the second area of the transparent substrate, and the lead electrode is disposed on a side of the light-shielding layer away from the transparent substrate.

6. The touch-screen conductive film according to claim 5, further comprising an adhesive layer disposed on the first area and the second area of the transparent substrate;
wherein the conductive layer and the light-shielding layer are connected to the transparent substrate via the adhesive layer, or, the adhesive layer covers the light shielding layer, the conductive layer is connected to the transparent substrate via the adhesive layer.

7. A method for manufacturing a touch-screen conductive film comprising:
providing a transparent substrate having a first area and a second area disposed surrounding the first area;
forming a conductive layer on the first area of the transparent substrate, wherein the conductive layer is formed by conductive wires intercrossed to each other; and
forming a lead electrode on the second area of the transparent substrate, wherein the lead electrode is electrically connected to the conductive wires.

8. The method for manufacturing the touch-screen conductive film according to claim 7, wherein the step of forming a conductive layer on the first area of the transparent substrate comprises:
forming a photoresist in the first area of the transparent substrate;
photoetching and developing the photoresist to obtain a conductive groove;
printing in the conductive groove with a conductive solution and drying the conductive solution;
removing remaining photoresist to obtain the conductive layer.

9. The method for manufacturing the touch-screen conductive film according to claim 7, wherein the step of forming a lead electrode on the second area of the transparent substrate comprises:
forming a photoresist in the second area of the transparent substrate;
photoetching and developing the photoresist to obtain a lead electrode groove;
printing in the lead electrode groove with a conductive solution and drying the conductive solution;
removing remaining photoresist to obtain the lead electrode.

10. The method for manufacturing the touch-screen conductive film according to claim 7, after the step of providing a transparent substrate, and before the step of forming a conductive layer on the first area of the transparent substrate, further comprising a step of coating adhesive glue in the first area and the second area of the transparent substrate to obtain an adhesive layer, wherein the conductive layer and the lead electrode are both formed on one side of the adhesive layer away from the transparent substrate.
